(19) United States
(12) Patent Application Publication
(10) Pub. No.: US 2002/0137304 A1
(43) Pub. Date: Sep. 26, 2002

(54) Method of reworking bump

(76) Inventors: Muh-Min Yih, Chiung-Lin Shiang (TW); Chin-Ying Tsai, Kaohsiung (TW)

Correspondence Address: J C Patents Inc, 4 Venture Suite 250, Irvine, CA, 92618, US

(21) Appl. No.: 09/853,988

(22) Filed: May 11, 2001

(30) Foreign Application Priority Data
Mar. 22, 2001 (TW) 90106704

(51) Int. Cl. H01L 21/76

(52) U.S. Cl. 438/411; 438/422

(57) ABSTRACT

A method of reworking a bump is provided. Failed bumps are chemically etched off the wafer. During etching, the etchant somewhat damages the passivation layer on the wafer. Therefore, a global metal layer is needed to cover the bonding pads and the passivation layer before a new under ball metallurgy (UBM) layer is formed. A complementary passivation layer is formed to cover the damaged passivation layer after the failed bumps are removed. Then, a new UBM layer and new bumps are formed. Alternatively, the failed bumps and UBM layer are chemically etched off without formation of a metal layer. Instead, a complementary passivation layer is formed to cover the damaged passivation layer. Finally, a new UBM layer and new bumps are formed. By chemical etching, the failed bumps can be reworked and the yield of the bump production can be increased.

### CROSS-REFERENCE TO RELATED APPLICATION

This application claims the priority benefit of Taiwan application serial no. 90106704, filed Mar. 22, 2001.

### BACKGROUND OF THE INVENTION

1. Field of the Invention

The present invention relates to a method of reworking a bump. More specifically, the present invention relates to a method of reworking a bump in which failed bumps are chemically etched off.

2. Description of the Related Art

As semiconductor technology progresses, electronic devices tend to have various functions, smaller dimensions, and greater memory, etc. Semiconductor package technology is dependent on the development of electronic devices.

High-density packages that meet commercial demands, such as ball grid array (BGA), chip scale packages (CSP) and multi-chip modules (MCM), have been developed and put into practice. In high-density packages, a short connection path will help to increase the transmission speed for signals. Therefore, bumps are increasingly used as connections in high-density packages.

A bump having larger height and higher uniformity is expected and required. However, some defects are generated after the bumps are formed on the wafer, such as a bridge between two adjacent bumps or bumps having different heights. In a conventional process for producing bumps, the chip on which failed bumps are found will be discarded.

### SUMMARY OF THE INVENTION

Therefore, it is one object of the present invention to provide a method of reworking a bump. Failed bumps are chemically etched off the wafer. During etching, the etchant somewhat damages the passivation layer on the wafer. Therefore, a global metal layer is needed to cover the bonding pads and the passivation layer before a new under ball metallurgy (UBM) layer is formed. A complementary passivation layer is formed to cover the damaged passivation layer after the failed bumps are removed. Then, a new UBM layer and new bumps are formed. Alternatively, the failed bumps and UBM layer are chemically etched off without formation of a metal layer. Thereafter, a complementary passivation layer is formed to cover the damaged passivation layer. Finally, a new UBM layer and new bumps are formed. By chemical etching, the failed bumps can be reworked and the yield of the bump production can be increased.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIGS. 1-5 are schematic views showing a process for reworking a bump according to the present invention; and

FIGS. 6-10 are schematic views showing a method of reworking a bump according to a second preferred embodiment of the present invention.

### DESCRIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

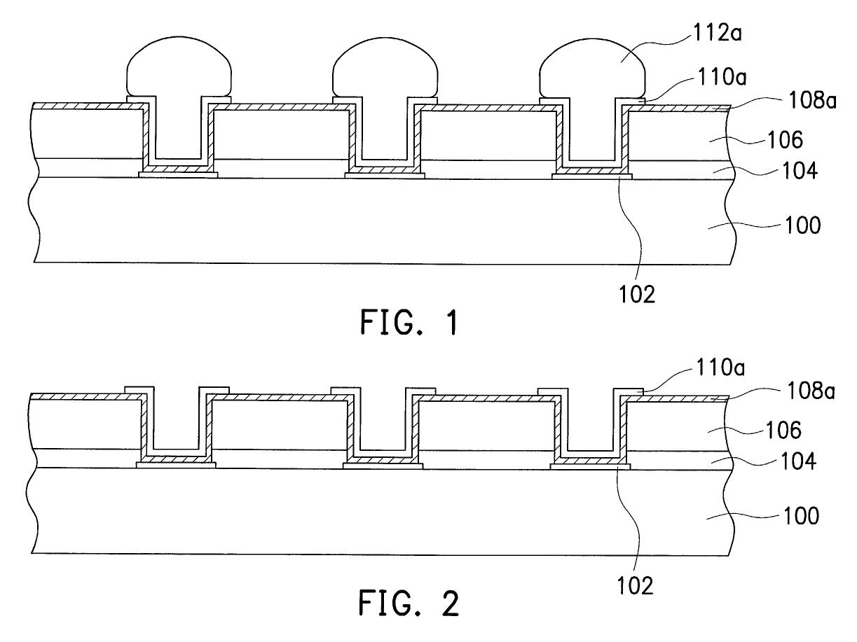

FIGS. 1-5 are schematic views showing a process for reworking a bump according to the present invention.

With reference to FIG. 1, a wafer having a plurality of chips thereon is provided. Each of chips is provided with a plurality of bonding pads 102 and a passivation layer 104 (106) that protects the chip and exposes the bonding pads. The passivation layer 104 can be made of silicon oxide or silicon nitride, for example. The material for the passivation layer 106 can be polyimide (PI), for example. A global metal layer 108a is formed over the wafer 100. An under ball metallurgy (UBM) layer 110a is formed on the metal layer 108a where a bump 112a is formed later. The UBM layer 110a can be a multi-layer configuration of chromium copper alloy/copper, for example. Then, a bump 112a is formed on the UMB 110a. The bump 112a can be formed of solder by using a stencil printing process and a reflow process, for example.

In this embodiment, layers made of a material other than metal also can be used instead of the metal layer 108a, as long as they provide protection to the wafer.

With reference to FIG. 2, a first chemical etching is carried out to remove a failed bump 112a on the wafer 100. In the first chemical etching, an etchant having a high etching rate to the bump 112a is preferably selected to completely remove the bump 112a.

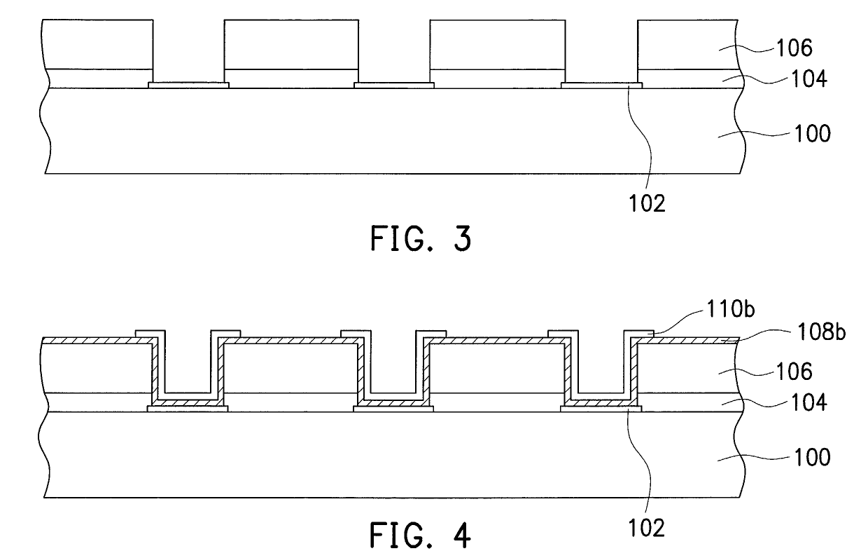

With reference to FIG. 3, a second chemical etching is carried out to remove the UBM layer 100a. In the second chemical etching, an etchant having a high etching rate to the UBM layer 110a is preferably selected to completely remove the UBM layer 110a. Then, a third chemical etching is carried out to remove the metal layer 108a. In the third chemical etching, an etchant having high etching selectivity of the metal layer 108a to the passivation layers 104, 106 is selected to prevent the passivation layers 104, 106 from being damaged by the etchant.

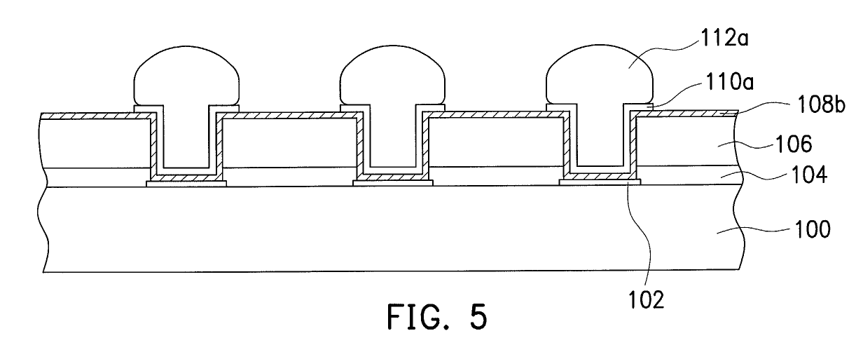

With reference to FIGS. 4 and 5, a new metal layer 108b and a new UBM layer 110b are formed on the bonding pads 102. Then, a new bump 112b is formed on the UBM layer 100b. The UBM layer 110b can be a multi-layer configuration of chromium copper alloy/copper. The bump 112b can be formed of solder by using a stencil printing process and a reflow process, for example.

During the second chemical etching, an etchant having high etching selectivity of the UBM layer 110a to the metal layer 108a is selected to completely remove the UBM layer 110a, while the metal layer 108a is still remained on the wafer 100 after the second chemical etching. The third chemical etching is not required. Instead, a new UBM layer 110b is formed on the original metal layer 108a and a new bump 112b is formed on the new UBM layer 110b. Thereafter, the original metal layer is removed.

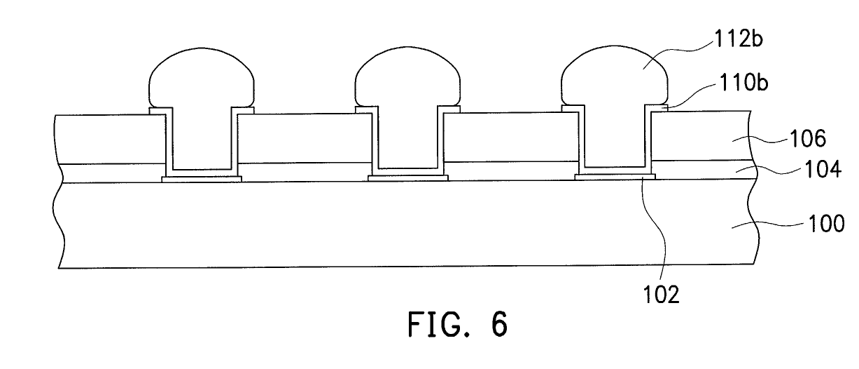

FIGS. 6-10 are schematic views showing a method of reworking a bump according to a second preferred embodiment of the present invention.

With reference to FIG. 6, a wafer having a plurality of chips thereon is provided. Each of chips is provided with a plurality of bonding pads 102 and a passivation layer 104 (106) that protects the chip and exposes the bonding pads. The passivation layer 104 can be made of silicon oxide or silicon nitride, for example. The material for the passivation layer 106 can be polyimide (PI), for example. An under ball metallurgy (UBM) layer 110a is formed on each of the bonding pads 102. The UBM layer 110a can be a multi-layer configuration of chromium copper alloy/copper, for example. Then, a bump 112a is formed on the UBM layer 110a. The bump 112a can be formed of solder by using a stencil printing process and a reflow process, for example.

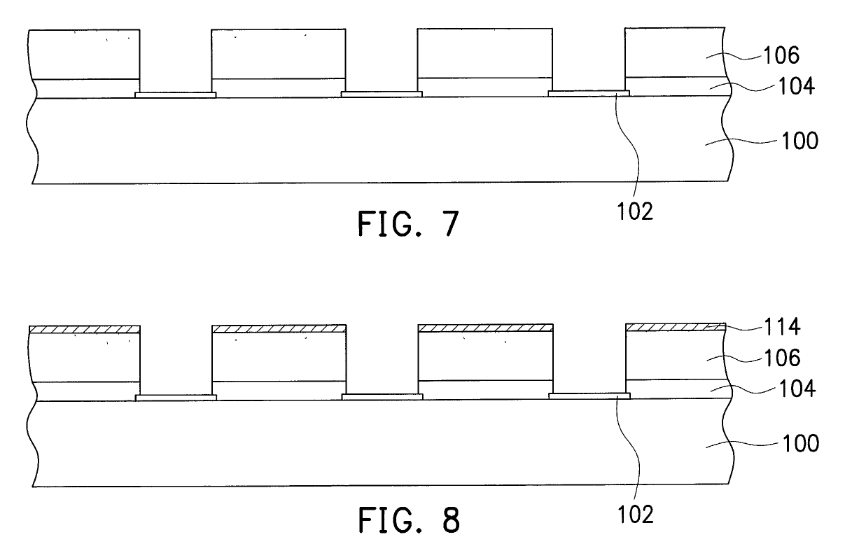

With reference to FIG. 7, a first chemical etching is carried out to remove a failed bump 112a on the wafer 100. Then, a second chemical etching is carried out to remove the UBM layer 110a.

In the first chemical etching, an etchant having high etching selectivity of the bump 112a to the passivation layers 104, 106 is preferably selected. In the second chemical etching, an etchant having high etching selectivity of the UBM layer 110a to the passivation layers 104, 106 is preferably selected to prevent the passivation layers 104, 106 from being damaged during the first and second etching processes.

With reference to FIG. 8, since the selected etchant somewhat damages the passivation layers 104, 106, a supplementary passivation layer 114 must be formed on the passivation layers 104, 106 to cover damaged portions of the passivation layers 104, 106 caused by the first and second etching processes.

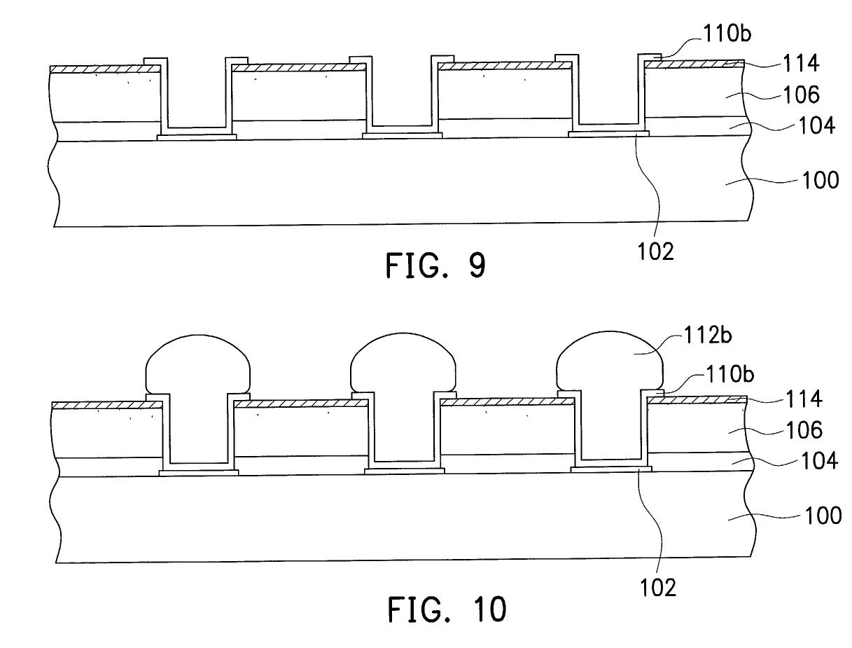

With reference to FIGS. 9-10, a new UBM layer 10b is formed on the bonding pads 102. Then, a new bump 112b is formed on the UBM layer 110b. The UBM layer 110b can be a multi-layer configuration of chromium copper alloy/copper. The bump 112b can be formed of solder by using a stencil printing process and a reflow process, for example.

From a view of foregoing, the method of reworking a bump according to the present invention can provide the following advantages:

The UBM layer and the bump on the wafer can be removed by chemical etching. A new UBM layer and a new bump are formed on the location where the old UBM layer and bump are removed. Therefore, an increased yield and reduced production cost can be achieved.

Alternatively, reworking the bump can be performed during bump production.

The failed bump and the UBM thereunder are removed by chemical etching. By using a metal layer or layers made of a material other than metal, the passivation layer can be protected from being damaged by the etchant. Alternatively, a complementary passivation layer is used to cover the original passivation layer that has been damaged by the etchant.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A method of reworking a bump, comprising:
providing a wafer that has a plurality of chips thereon, each of the chips being provided with a plurality of bonding pads and a passivation layer that protects the chip and exposes the bonding pads, wherein each of the bonding pads has a first under ball metallurgy (UBM) layer thereon and the first UBM layer is provided with a first bump;
performing a first chemical etching to remove the first bumps;
performing a second etching to remove the first UBM layers;
forming a second UBM layer on each of the bonding pads; and
forming a second bump on the second UBM layer.

2. The method of claim 1, wherein the first bump and the second bump are made of solder.

3. The method of claim 1, wherein an etchant having high etching selectivity of the first bump to the passivation layer is used in the first chemical etching.

4. The method of claim 1, wherein an etchant having high etching selectivity of the UBM layer to the passivation layer is used in the second chemical etching.

5. The method of claim 1, wherein the global metal layer is formed over the wafer before the second UBM layer is formed in order to prevent the passivation layer from being damaged during the first and second chemical etching processes.

6. The method of claim 1, further forming a complementary passivation layer after the second etching to cover the damaged passivation layer caused by the first and second chemical etchings.

7. A method of reworking a bump, applicable to a wafer having a plurality of chips thereon, each of the chips being provided with a plurality of bonding pads and a passivation layer that protects the chip and exposes the bonding pads, the method comprising:
forming a global metal layer over the wafer;
forming a first under ball metallurgy (UBM) layer on the metal layer above the bonding pads;
forming a first bump on the first UBM layer;
performing a first chemical etching to remove the first bump;
performing a second etching to remove the first UBM layer;
forming a second UBM layer on each of the bonding pads; and
forming a second bump on the second UBM layer.

8. The method of claim 7, wherein the first bump and the second bump are made of solder.

9. The method of claim 7, wherein an etchant having high etching selectivity of the first bump to the passivation layer is used in the first chemical etching.

10. The method of claim 7, wherein an etchant having high etching selectivity of the UBM layer to the passivation layer is used in the second chemical etching.

11. The method of claim 7, further comprising the steps of performing a third chemical etching to remove the metal layer; and forming a second global metal layer over the wafer.

12. A method of reworking a bump, comprising:
providing a wafer that has a plurality of chips thereon, each of the chips being provided with a plurality of bonding pads and a passivation layer that protects the chip and exposes the bonding pads, wherein each of the bonding pads has a first under ball metallurgy (UBM) layer thereon and the first UBM layer is provided with a first bump;
performing a first chemical etching to remove the first bumps;
performing a second etching to remove the first UBM layers;
forming a complementary passivation layer on the passivation layer to cover the damaged portions of the passivation layer caused by the first and second chemical etching processes;
forming a second UBM layer on each of the bonding pads; and
forming a second bump on the second UBM layer.

13. The method of claim 12, wherein the first bump and the second bump are made of solder.

14. The method of claim 12, wherein an etchant having high etching selectivity of the first bump to the passivation layer is used in the first chemical etching.

15. The method of claim 12, wherein an etchant having high etching selectivity of the UBM layer to the passivation layer is used in the second chemical etching.
